(19) United States
(12) Patent Application Publication
(10) Pub. No.: US 2026/0322156 A1
(43) Pub. Date: Oct. 15, 2026

(54) POWER SUPPLY APPARATUS

(71) Applicant: TMEIC Corporation, Tokyo (JP)

(72) Inventors: Keisuke OHNISHI, Chuo-ku (JP); Hiroshi MASUNAGA, Chuo-ku (JP); Shigeo NUMOTO, Chuo-ku (JP)

(73) Assignee: TMEIC Corporation, Tokyo (JP)

(21) Appl. No.: 19/100,399

(22) PCT Filed: Jul. 10, 2023
(86) PCT No.: PCT/JP2023/025391

§ 371 Date: Jan. 31, 2025

(51) Int. Cl. H02J 9/06; H01M 10/0525; H01M 10/42; H02J 3/17; H02J 7/00; H02J 7/06; H02J 7/82

(52) U.S. Cl. CPC H02J 9/062; H01M 10/0525; H01M 10/425; H02J 7/06; H02J 7/82; H02J 7/865; H02J 3/17; H02J 2207/20

(57) ABSTRACT

A first power converter selectively performs a charging operation to convert a portion of first alternating-current power received from a power system to direct-current power and store the direct-current power in a power storage device, and a discharging operation to convert direct-current power of the power storage device to second alternating-current power. When the power system is healthy, a controller controls the charging operation so that the power storage device is fully charged. When a demand response preannouncement signal is received from a server, the controller controls the discharging operation to supply the load with a total power of the first alternating-current power and the second alternating-current power, and stops the discharging operation in response to the power storage device having an SOC reduced to a standby SOC. The controller controls the discharging operation or the charging operation in response to a demand response command received from the server.

### TECHNICAL FIELD

The present disclosure relates to a power supply apparatus.

### BACKGROUND ART

For example, Japanese Patent Laying-Open No. H08-289470 (PTL 1) discloses a power supply apparatus that supplies power from a commercial power supply to a load. The power supply apparatus comprises an uninterruptible power supply that supplies the load with power that is stored in a power storage device when the commercial power supply fails, a demand monitoring device that monitors the load's power usage (or demand), and a demand controller. The demand controller is configured to calculate the uninterruptible power supply's surplus power and supply the calculated surplus power to the load when the load's power usage is predicted to exceed a contracted amount of power.

### CITATION LIST

### PATENT LITERATURE

PTL 1: Japanese Patent Laying-Open No. H08-289470

### SUMMARY OF INVENTION

### Technical Problem

In recent years, in order to balance demand for power and supply of power in a power system, a demand response (DR) has been proposed to control a consumer's power usage. In one aspect, an electric utility company can coordinate with an aggregator to balance power demand and supply by making a predetermined request to each consumer through a DR command. The DR command includes a positive DR command for requesting an increased amount of demand for power and a negative DR command for requesting a reduced amount of demand for power.

The consumer can contribute to the power system's demand and supply adjustment by charging and discharging the power storage device in response to the DR command received from the aggregator. However, on the other hand, when the DR is executed, the power storage device varies in state of charge (SOC), and when the power system fails while or after the DR is executed, the power storage device may not have stored therein sufficient power necessary for compensation for outage. This would impair the power supply apparatus's inherent function to compensate for outage, and the load may no longer be able to receive steady alternating-current power.

The present disclosure has been made in view of the above problem, and contemplates a power supply apparatus that can contribute to a power system's demand and supply adjustment while ensuring that the power system supplies a load with power when the power system fails.

### Solution to Problem

A power supply apparatus according to one aspect of the present disclosure is connected between a power system and a load. The power supply apparatus supplies the load with a first alternating-current power supplied from the power system when the power system is healthy, and the power supply apparatus supplies the load with a second alternating-current power when the power system fails. The power supply apparatus comprises a first power converter and a controller. The first power converter selectively performs a charging operation to convert a portion of the first alternating-current power to direct-current power and store the direct-current power in a power storage device, and a discharging operation to convert direct-current power in the power storage device to the second alternating-current power. The controller is communicatively connected to a server that adjusts power demand and supply in the power system. When the power system fails, the controller controls the discharging operation in the first power converter to supply the load with the second alternating-current power. For the power storage device, a reference SOC value that is equal to or larger than an SOC necessary for supplying the second alternating-current power from the power storage device to the load after the power system fails before a predetermined period of time for compensation elapses, and a standby SOC that is larger than the reference SOC value, are set. When the power system is healthy, the controller controls the charging operation in the first power converter so that the power storage device attains a fully charged state. When a demand response preannouncement signal is received from the server to adjust an amount of demand in the power system, the controller controls the discharging operation in the first power converter to supply the load with a total power of the first alternating-current power and the second alternating-current power. The controller stops the discharging operation in response to the power storage device having an SOC reduced to the standby SOC. The controller controls the discharging operation or the charging operation in the first power converter in response to a demand response command received from the server.

### Advantageous Effects of Invention

According to the present disclosure, a power supply apparatus that can contribute to a power system's demand and supply adjustment while ensuring that the power system supplies a load with power when the power system fails, can be provided.

### BRIEF DESCRIPTION OF DRAWINGS

FIG. 1 is a diagram for illustrating a configuration of a power supply apparatus according to an embodiment of the present disclosure.

FIG. 2 is a diagram for illustrating an example of a hardware configuration of a controller.

FIG. 3 is a diagram for illustrating an operation of an MPC when a power system is healthy.

FIG. 4 is a diagram for illustrating an operation of the MPC when the power system fails.

FIG. 5 is a diagram for illustrating an operation of the MPC when a negative DR command is received.

FIG. 6 is a diagram for illustrating how charging/discharging a power storage device is controlled when the negative DR is executed.

FIG. 7 is a diagram for illustrating an operation of the MPC when a positive DR command is received.

FIG. 8 is a diagram for illustrating how charging/discharging the power storage device is controlled when the positive DR is executed.

FIG. 9 is a flowchart of a procedure of a process for how charging/discharging the power storage device is controlled according to the present embodiment.

FIG. 10 is a flowchart of a procedure of a process for how charging/discharging the power storage device is controlled according to the present embodiment.

FIG. 11 is a diagram for illustrating a configuration of a power supply apparatus according to a modification of the present embodiment.

### DESCRIPTION OF EMBODIMENTS

Hereinafter reference will be made to the drawings to describe an embodiment of the present disclosure. Note that in the figures, identical or equivalent components are identically denoted and will not be described repeatedly.

### Configuration of Power Supply Apparatus

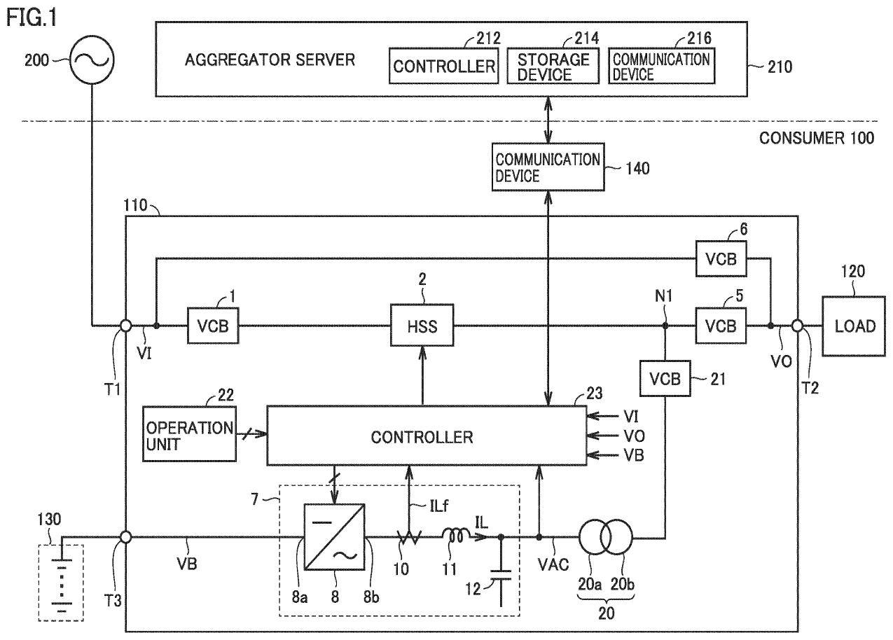

FIG. 1 is a diagram for illustrating a configuration of a power supply apparatus according to an embodiment of the present disclosure. In FIG. 1, a multiple power compensator (MPC) will be described as a manner of the power supply apparatus.

As illustrated in FIG. 1, an MPC 110 is installed in a consumer 100 that receives power from a power system 200. In consumer 100, a load 120, a power storage device 130, and a communication device 140 are further installed.

MPC 110 is a device connected between power system 200 and load 120 for supplying load 120 with steady alternating-current power without momentary interruption when a phenomenon in which alternating voltage supplied from power system 200 decreases or is zero for a relatively short period of time (for example of less than one second) (i.e., a momentary voltage dip or a momentary power outage) occurs.

Note that a device that supplies load 120 with alternating-current power when a phenomenon in which alternating voltage supplied from power system 200 is zero for a relatively long period of time (for example of one second or more) (i.e., a power outage) occurs is referred to as an uninterruptible power supply (UPS). In the present specification, an MPC and a UPS will collectively be referred to as a “power supply apparatus”. In the present specification, a momentary voltage dip, a momentary power outage and a power outage of power system 200 will collectively be referred to as “outage”.

MPC 110 comprises an input terminal T1, an output terminal T2, a direct-current terminal T3, vacuum circuit breakers (VCBs) 1, 5, 6 and 21, a high speed switch (HSS) 2, a power converter 7, a transformer 20, an operation unit 22, and a controller 23.

Input terminal T1 receives alternating voltage VI of a commercial frequency supplied from power system 200. An instantaneous value of alternating voltage VI is detected by controller 23. When alternating voltage VI falls below a lower limit value, controller 23 determines that an outage of alternating voltage VI has occurred.

Output terminal T2 is connected to load 120. Load 120 is driven by alternating voltage VO supplied from output terminal T2. An instantaneous value of alternating voltage VO is detected by controller 23.

Direct-current terminal T3 is connected to power storage device 130. Power storage device 130 stores direct-current power. Power storage device 130 is, for example, a secondary battery such as a lithium ion battery. However, a lead-acid battery may be used instead of the lithium ion battery. An electric double layer capacitor may be used instead of the secondary battery. Direct voltage VB on direct-current terminal T3 is detected by controller 23. Direct voltage VB corresponds to an inter-terminal voltage of power storage device 130 (hereinafter also referred to as a “battery voltage”).

While MPC 110 receives three-phase alternating voltage from power system 200 and supplies load 120 with three-phase alternating voltage, FIG. 1 illustrates only a circuit for one phase to simplify the figure and the description.

VCB1, high-speed switch 2, and VCB5 are connected in series between input terminal T1 and output terminal T2. VCBs 1 and 5 are turned on while MPC 110 normally operates, and turned off for example when high-speed switch 2 undergoes maintenance or bypass power feeding is performed.

High-speed switch 2 includes a semiconductor switch and a mechanical switch connected in series. The semiconductor switch and the mechanical switch are controlled by controller 23, and turned on when alternating voltage VI is normal (or when power system 200 is healthy) and turned off when alternating voltage VI is not normal (or when power system 200 fails).

The semiconductor switch characteristically has a higher operating speed and a lower breakdown voltage than the mechanical switch. The mechanical switch characteristically has a lower operating speed and a higher breakdown voltage than the semiconductor switch. The semiconductor switch and the mechanical switch are connected in series to configure high-speed switch 2 that is instantaneously turned off when a momentary voltage dip occurs, and has a high breakdown voltage.

VCB 6 is connected between input terminal T1 and output terminal T2. VCB 6 is turned off while MPC 110 normally operates, and turned on for example when bypass power feeding is performed. When VCB 6 is turned on, alternating voltage VI is supplied from power system 200 to load 120 via VCB 6, and load 120 is thus operated.

Power converter 7 includes a bidirectional converter 8, a current detector 10, a reactor 11, and a capacitor 12. Bidirectional converter 8 has a direct-current terminal 8a connected to direct-current terminal T3, and an alternate-current terminal 8b connected to a primary winding 20a of transformer 20 via reactor 11. Transformer 20 has a secondary winding 20b connected via VCB 21 to a node N1 located between high-speed switch 2 and VCB 5. An instantaneous value of alternating voltage VAC appearing on primary winding 20a of transformer 20 is detected by controller 23. Power converter 7 corresponds to one embodiment of a “first power converter”.

Bidirectional converter 8 is what is well-known including a plurality of semiconductor switching elements and a plurality of diodes, and is controlled by controller 23 for example through PWM (Pulse Width Modulation). Turning on and off each semiconductor switching element included in bidirectional converter 8 at a predetermined frequency can convert alternating-current power to direct-current power and vice versa.

In one aspect, when power system 200 is healthy, bidirectional converter 8 receives alternating-current power supplied from power system 200 via VCB 1, high-speed switch 2, VCB 21, transformer 20, and reactor 11, converts the received alternating-current power to direct-current power, and stores the direct-current power in power storage device 130. When power system 200 fails, bidirectional converter 8 converts direct-current power of power storage device 130 to alternating-current power and outputs the alternating-current power to alternate-current terminal 8b. The alternating-current power is supplied to load 120 via reactor 11, transformer 20, and VCBs 21 and 5. Thus, bidirectional converter 8 is configured to be capable of selectively performing a charging operation to store direct-current power in power storage device 130 and a discharging operation to supply load 120 with direct-current power of power storage device 130.

Current detector 10 detects a current IL flowing through reactor 11, and provides a signal ILf indicating the detected value to controller 23.

Reactor 11 and capacitor 12 constitute an alternating-current filter. The alternating-current filter is a low-pass filter to pass a current of a commercial frequency and interrupt a current of a switching frequency generated in bidirectional converter 8. In other words, the alternating-current filter converts a voltage that is output from bidirectional converter 8 to alternating voltage VAC in a sinusoidal waveform.

Transformer 20 receives and outputs alternating-current power between node N1 and power converter 7. VCB 21 is turned on while MPC 110 normally operates, and turned off for example when high-speed switch 2 or power converter 7 undergoes maintenance.

Operation unit 22 includes a plurality of buttons, a plurality of switches, a display, and so forth. A user of MPC 110 can operate operation unit 22 to input instructions to activate, stop, and automatically/manually drive MPC 110 and set a variety of types of conditions. Operation unit 22 provides a signal indicating the user's instructions or the like to controller 23.

Controller 23 generally controls MPC 110 based on a signal received from operation unit 22, alternating voltages VI, VO and VAC, direct voltage VB, signal ILf output from current detector 10, and so forth.

In one aspect, when power system 200 is healthy, controller 23 controls bidirectional converter 8, based on alternating voltage VAC, direct voltage VB, and signal ILf output from current detector 10, so that direct voltage (or battery voltage) VB on direct-current terminal T3 is a reference direct voltage VBr. When power system 200 fails, controller 23 controls bidirectional converter 8 so that alternating voltage VO on output terminal T2 is a reference alternating voltage VOr.

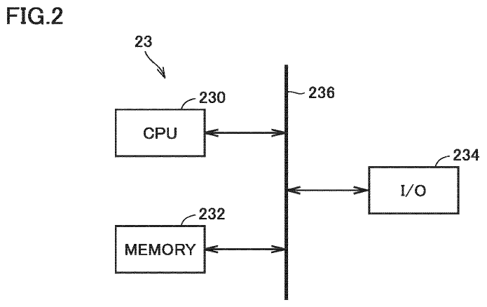

FIG. 2 is a diagram for illustrating a hardware configuration example of controller 23. Typically, controller 23 can be configured by a microcomputer having a predetermined program stored therein in advance.

For example, as illustrated in FIG. 2, controller 23 includes a CPU (Central Processing Unit) 230, a memory 232, and an input/output (I/O) circuit 234. CPU 230, memory 232, and I/O circuit 234 can communicate data with one another via a bus 236. A program is stored in advance in a partial area of memory 232, and a variety of types of functions can be implemented by CPU 230 executing the program.

Alternatively, in contrast to the FIG. 2 example, at least a part of controller 23 can be configured using a circuit such as an FPGA (Field Programmable Gate Array) or an ASIC (Application Specific Integrated Circuit). At least a part of controller 23 may also be configured by an analog circuit.

Returning to FIG. 1, controller 23 is communicably connected to communication device 140. Communication device 140 is a device capable of communicating with an aggregator server 210 via a communication network (not shown), and communicates a variety of types of information with aggregator server 210.

Aggregator server 210 is a server managed and operated by an aggregator. An aggregator is an operator that collectively manages energy resources that many consumers have, and mediates between the consumers and an electric utility company to balance power demand and supply and make most use of each consumer's energy resource.

The electric utility company can cooperate with the aggregator to balance power demand and supply by a demand response (hereinafter also referred to as “DR”). The DR is an approach to balance power demand and supply by making a predetermined request to each consumer by a demand response command (hereinafter also referred to as a “DR command”). The DR command includes a DR command requesting an increased amount of demand for power (hereinafter also referred to as a “positive DR command”) and a DR command requesting a reduced amount of demand for power (hereinafter also referred to as a “negative DR command”).

For example, on a hot summer day or a cold winter day when a demand for power rapidly increases and power demand and supply becomes tight, the electric utility company requests the aggregator for a reduced amount of demand for power.

In response to the request, the aggregator outputs a negative DR command to the consumers managed by the aggregator. The consumers cooperate to reduce their demands for power, which are collected by the aggregator and provided to the electric utility company.

When renewable energy through solar power generation, wind power generation and so forth is generated in an increased amount and an amount of power supplied exceeds an amount of power demanded, the electric utility company requests the aggregator for an increased amount of demand for power. In response to the request, the aggregator outputs a positive DR command to the consumers managed by the aggregator.

By cooperating for the DR in response to such a request, each consumer can obtain a reward. The aggregator receives a reward from the electric utility company and mediates for payment to each consumer.

Aggregator server 210 includes a controller 212, a storage device 214, and a communication device 216. Controller 212 includes a processor, and is configured to perform predetermined information processing and control communication device 216. Storage device 214 is configured to be capable of storing a variety of types of information. Communication device 216 includes a variety of types of communication I/Fs. Controller 212 is configured to externally communicate through a communication device 216.

In the present embodiment, controller 23 is configured to control bidirectional converter 8 in response to a DR command (a positive DR command or a negative DR command) received from aggregator server 210 via communication device 140 while power system 200 is healthy.

Specifically, when a negative DR command is received from aggregator server 210, controller 23 controls bidirectional converter 8 so that a total power of alternating-current power supplied from power system 200 and alternating-current power supplied from power storage device 130 via bidirectional converter 8 is supplied to load 120.

In this way, a portion of alternating-current power supplied to load 120 can be catered for by the direct-current power of power storage device 130 to reduce alternating-current power supplied from power system 200 to consumer 100. Consumer 100 can thus contribute to suppression in amount of demand for power, as requested by the electric utility company, and can obtain a reward depending on its amount of contribution.

When a positive DR command is received from aggregator server 210, controller 23 controls bidirectional converter 8 to perform a charging operation to store direct-current power in power storage device 130. Thus, a total power of alternating-current power supplied to load 120 and the power stored in power storage device 130 can be supplied from power system 200 to increase alternating-current power supplied from power system 200 to consumer 100. As a result, consumer 100 can contribute to an increase in amount of demand for power as requested by the electric utility company, and can obtain a reward depending on its amount of contribution.

However, charging and discharging power storage device 130 in response to a DR command received from aggregator server 210 varies power storage device 130 in SOC (State Of Charge). Therefore, when power system 200 fails while or after the DR is executed, power storage device 130 may not have stored therein sufficient power necessary for compensation for outage. This would impair an inherent function of MPC 110 to compensate for outage, and load 120 may no longer be able to receive steady alternating-current power.

In order to avoid such a situation, MPC 110 according to the present embodiment controls charging/discharging power storage device 130 so as to be able to contribute to demand/supply adjustment for power system 200 as requested by the electric utility company while ensuring compensation for load 120 for outage.

### Operation of MPC

An operation of MPC 110 shown in FIG. 1 will now be described.

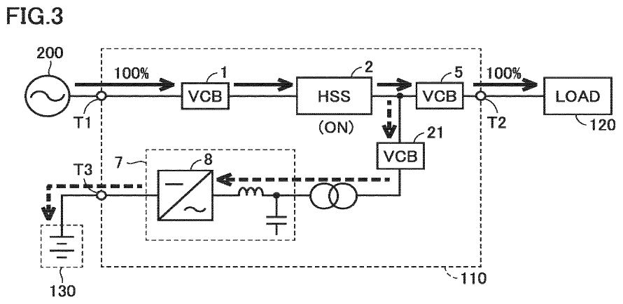

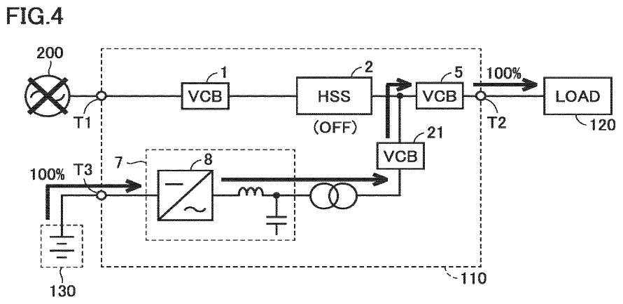

FIGS. 3 and 4 are diagrams for illustrating an operation of MPC 110 when it normally operates. When the MPC normally operates, VCBs 1 and 5 are turned on and VCB 6 (not shown) is turned off. FIG. 3 indicates by arrows a flow of power supplied from MPC 110 to load 120 when power system 200 is healthy. When power system 200 is healthy, HSS 2 is turned on, and alternating-current power is supplied from power system 200 to load 120 via VCB 1, HSS 2 and VCB 5, and load 120 is thus operated.

Further, alternating-current power is supplied from power system 200 to power converter 7 via VCB 1, HDD 2 and VCB 21, and the alternating-current power is converted to direct-current power by bidirectional converter 8 and stored in power storage device 130.

Controller 23 controls bidirectional converter 8 so that direct voltage (or battery voltage) VB on direct-current terminal T3 is reference direct voltage VBr. Reference direct voltage VBr is set based on an OCV that power storage device 130 has when power storage device 130 is in a fully charged state (SOC=100%) on the OCV-SOC curve of power storage device 130.

FIG. 3 shows a case in which load 120 has a power consumption of 100% and power system 200 supplies 100% of the power. It is assumed that power storage device 130 has already been sufficiently charged and a sufficiently small current flows to power storage device 130.

FIG. 4 indicates by arrows a flow of power supplied from MPC 110 to load 120 when power system 200 fails. When power system 200 fails, HSS 2 is turned off to disconnect power system 200 from load 120.

Controller 23 controls bidirectional converter 8 so that alternating voltage VO on output terminal T2 is reference alternating voltage VOr. As a result, 100% of the power is supplied from power storage device 130 to power converter 7, and 100% of the power is supplied from power converter 7 to load 120. Load 120 thus continues to operate.

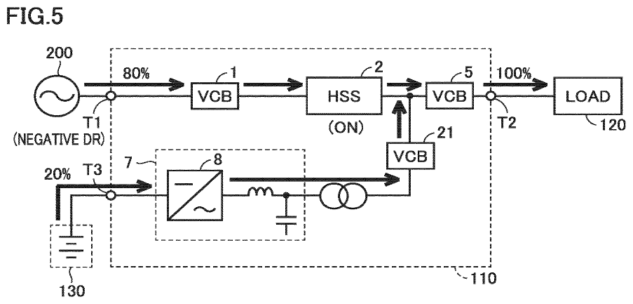

FIG. 5 is a diagram for illustrating an operation of MPC 110 when a negative DR command is received from aggregator server 210. FIG. 5 indicates by arrows a flow of power supplied from MPC 110 to load 120.

FIG. 5 shows a case in which load 120 has a power consumption of 100% and power system 200 supplies load 120 with 80% of the power as the negative DR is executed. Controller 23 controls bidirectional converter 8 so that alternating voltage VO on output terminal T2 is reference alternating voltage VOr. As a result, 20% of the power is supplied from power storage device 130 to load 120 via power converter 7. That is, the 80% of the power that is supplied from power system 200 and the 20% of the power that is supplied from power storage device 130 are summed together to supply 100% of the power supplied to load 120.

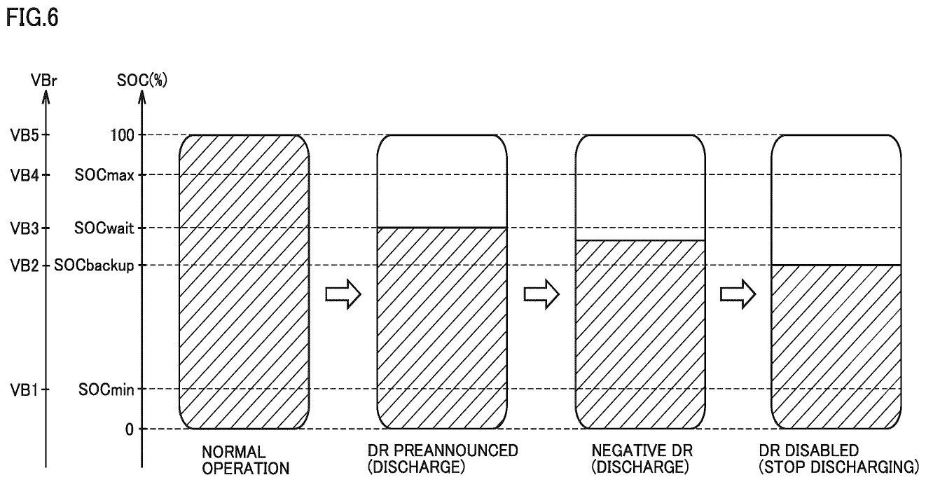

FIG. 6 is a diagram for illustrating how charging/discharging power storage device 130 is controlled when the negative DR is executed. FIG. 6 schematically illustrates how power storage device 130 changes in SOC as it is charged/discharged as controlled.

As shown in FIG. 6, for the SOC of power storage device 130, determination values SOCmin, SOCbackup, SOCwait, and SOCmax are set as references for controlling charging and discharging of power storage device 130. SOC=0% corresponds to an empty state of power storage device 130, and SOC=100% corresponds to the fully charged state of power storage device 130.

For the SOC, a prohibition region is set to prohibit power storage device 130 from discharging power in order to prevent overdischarge. The SOCmin is set based on the prohibition region. When SOC<SOCmin, power storage device 130 is prohibited from discharging power.

For the SOC is further set a prohibition region in which charging power storage device 130 is prohibited while a DR is executed. When a secondary battery such as a lithium ion battery is charged, in general, constant current charging is switched to constant voltage charging depending on the SOC. Specifically, at an initial stage of charging, constant current charging is performed to keep a charging current constant. And once the SOC has reached a predetermined value while the constant current charging is performed, the constant current charging is switched to constant voltage charging to keep the battery voltage constant.

While the constant voltage charging is performed, the charging current is smaller than that during the constant current charging, resulting in limited charged power. Therefore, when power storage device 130 is switched from constant current charging to constant voltage charging while a positive DR is executed, as will be described hereinafter, power storage device 130 may not be able to receive power corresponding to an amount of power adjusted as requested by the aggregator (or the amount of the positive DR). In order to stabilize power adjustment, when SOC>SOCmax while a positive DR is executed, controller 23 shall stop charging power storage device 130. The SOCmax corresponds to one embodiment of an “upper SOC limit value”. The SOCmax can be set based for example on an SOC that power storage device 130 has when power storage device 130 is switched from constant current charging to constant voltage charging.

The SOCbackup is an SOC for ensuring a function of MPC 110 as a backup power supply (i.e., a function to compensate for outage) when power system 200 fails. The SOCbackup is set to be equal to or larger than an amount of power stored for compensation for outage. The amount of power stored for compensation for outage is an amount of power stored that is required for continuing to supply power from power storage device 130 to load 120 for a predetermined period of time for compensation when power system 200 fails. Accordingly, ensuring the function to compensate for outage entails keeping the SOC equal to or larger than the SOCbackup when power system 200 is healthy. The SOCbackup corresponds to one embodiment of a “reference SOC value”.

The SOCbackup is set to be larger than the SOCmin and smaller than the SOCmax. Setting SOCbackup<SOCmax allows power storage device 130 to be responsible for supplying a portion of power supplied to load 120 while ensuring that an amount of power is stored for compensation for outage when a negative DR is executed, as shown in FIG. 5. Further, when a positive DR is executed as will be described hereinafter, a portion of power supplied from power system 200 can be stored in power storage device 130 while ensuring that an amount of power is stored for compensation for outage.

The SOCwait is set to be larger than the SOCbackup and smaller than the SOCmax. The SOCwait corresponds to a “standby SOC” for setting power storage device 130 in a state capable of enabling either the charging operation or the discharging operation in preparation for executing a DR.

FIG. 6 shows a relationship between the SOC of power storage device 130 and direct voltage (or battery voltage) VB on direct-current terminal T3. Battery voltage VB is based on the OCV-SOC curve of power storage device 130. A voltage VB1 corresponds to an OCV that the power storage device has when the SOC is the SOCmin on the OCV-SOC curve. A voltage VB2 corresponds to an OCV that the power storage device has when the SOC is the SOCbackup on the OCV-SOC curve. A voltage VB3 corresponds to an OCV that the power storage device has when the SOC is the SOCwait on the OCV-SOC curve. A voltage VB4 corresponds to an OCV that the power storage device has when the SOC is the SOCmax on the OCV-SOC curve. A voltage VB5 corresponds to an OCV that the power storage device has when SOC=100% on the OCV-SOC curve.

In the normal operation, controller 23 sets a target voltage for battery voltage VB, or reference direct voltage VBr, to VB5, and controls bidirectional converter 8 so that battery voltage VB is reference direct voltage VBr (=VB5). This keeps power storage device 130 in SOC at 100% (or in the fully charged state). However, when a positive DR starts in response to a request issued from the aggregator, and power storage device 130 also has an SOC in the fully charged state, power storage device 130 will not be able to receive a portion of power supplied from power system 200.

Accordingly, before the DR is executed, controller 23 receives from aggregator server 210 a DR preannouncement signal preannouncing that the DR will start, and in response thereto, controller 23 controls bidirectional converter 8 so that a total power of alternating-current power supplied from power system 200 and alternating-current power supplied from power storage device 130 via bidirectional converter 8 is supplied to load 120.

Bidirectional converter 8 performs a discharging operation of power storage device 130, and power storage device 130 decreases in SOC. When the SOC decreases to the SOCwait, controller 23 stops operating bidirectional converter 8 and hence stops discharging power storage device 130. Note that a time when aggregator server 210 transmits the DR preannouncement signal can be a time before a DR starts by a predetermined period of time.

When the DR preannouncement signal is received as described above, power storage device 130 can have an SOC reduced to the SOCwait before the DR is executed so that when the DR is a positive DR, power storage device 130 can receive a portion of power supplied from power system 200. Further, the SOCwait larger than the SOCbackup ensures that an amount of power is stored for compensation for outage.

In FIG. 6, a DR preannouncement signal is received, and thereafter when a negative DR command is received, controller 23 responds to a request received from the aggregator for an adjusted amount of power (or an amount of a negative DR) by controlling bidirectional converter 8 to supply load 120 with a total power of alternating-current power supplied from power system 200 and alternating-current power supplied from power storage device 130 via bidirectional converter 8. Bidirectional converter 8 performs a discharging operation of power storage device 130, and power storage device 130 decreases in SOC.

When power storage device 130 has an SOC reduced to be equal to or smaller than the SOCbackup, controller 23 transmits a DR disabling signal to aggregator server 210 in order to indicate that the negative DR can no more be executed. Controller 23 stops operating bidirectional converter 8 and hence stops discharging power storage device 130.

When a negative DR is executed and subsequently power system 200 fails, then, as illustrated in FIG. 4, bidirectional converter 8 performs a discharging operation of power storage device 130 to supply power from power storage device 130 to load 120 via power converter 7. When this is done, power storage device 130 has an amount of power stored therein for compensation for outage, and load 120 can be driven for a period of time for compensation.

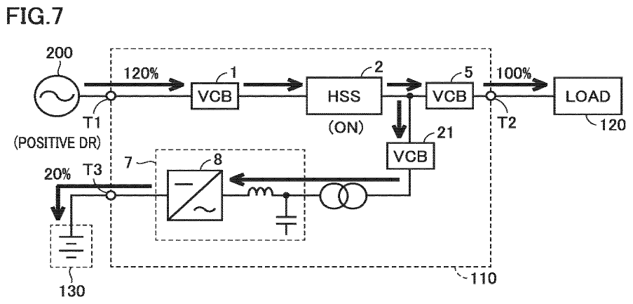

FIG. 7 is a diagram for illustrating an operation of MPC 110 when a positive DR command is received from aggregator server 210. FIG. 7 indicates by arrows a flow of power supplied from MPC 110 to load 120.

FIG. 7 shows a case in which load 120 has a power consumption of 100% and power system 200 supplies 120% of the power as a positive DR is executed.

Controller 23 sets reference direct voltage VBr to VB4, and controls bidirectional converter 8 so that battery voltage VB is reference direct voltage VBr (=VB4). Thus, of the power of the 120% supplied from power system 200, 100% of the power is supplied to load 120, and the remaining 20% of the power is supplied to power storage device 130 via power converter 7.

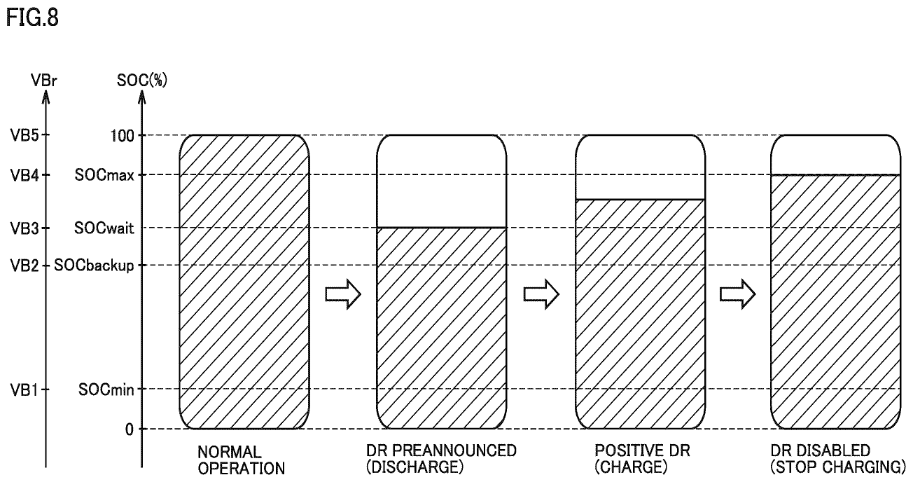

FIG. 8 is a diagram for illustrating how charging/discharging power storage device 130 is controlled when the positive DR is executed. FIG. 8 schematically illustrates how power storage device 130 changes in SOC as it is charged/discharged as controlled.

Before a DR preannouncement signal is received from aggregator server 210, controller 23 sets a target voltage for battery voltage VB, or reference direct voltage VBr, to VB5, and controls bidirectional converter 8 so that battery voltage VB is reference direct voltage VBr (=VB5). This keeps power storage device 130 at 100% in SOC.

Upon receiving the DR preannouncement signal, controller 23 controls bidirectional converter 8 so that a total power of alternating-current power supplied from power system 200 and alternating-current power supplied from power storage device 130 via bidirectional converter 8 is supplied to load 120. Bidirectional converter 8 performs a discharging operation of power storage device 130, and power storage device 130 decreases in SOC. When power storage device 130 has an SOC reduced to the SOCwait, controller 23 stops operating bidirectional converter 8 and hence stops discharging power storage device 130.

The DR preannouncement signal is received, and thereafter when a positive DR command is received, controller 23 responds to a request received from the aggregator for the amount of the positive DR by controlling bidirectional converter 8 to supply power storage device 130 with a portion of alternating-current power supplied from power system 200. Bidirectional converter 8 performs a charging operation of power storage device 130, and power storage device 130 increases in SOC.

Once power storage device 130 has an SOC having reached the SOCmax, controller 23 transmits a DR disabling signal to aggregator server 210 in order to indicate that the positive DR can no more be executed. Controller 23 stops operating bidirectional converter 8 and hence stops charging power storage device 130.

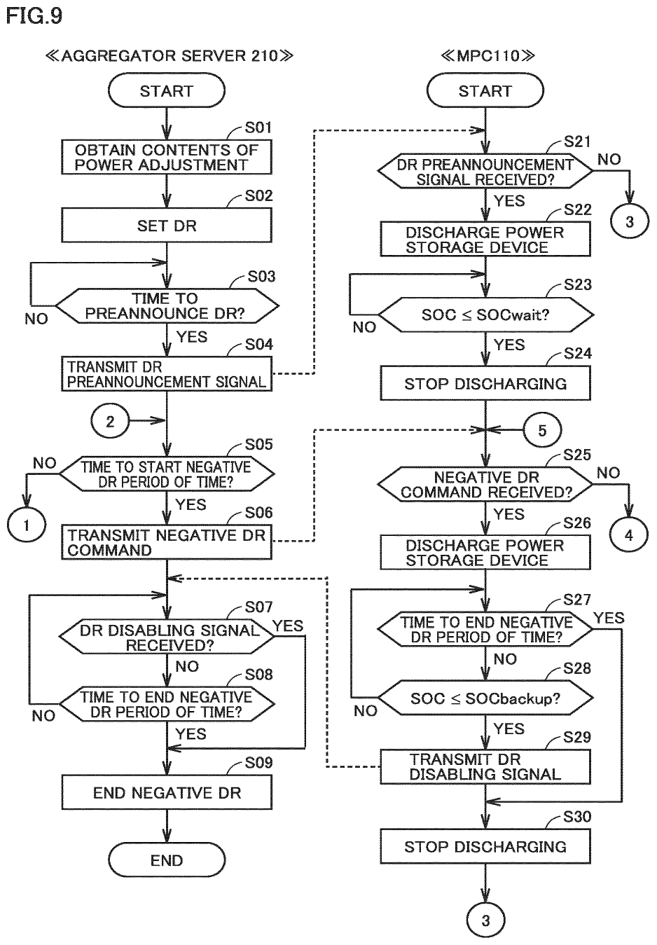

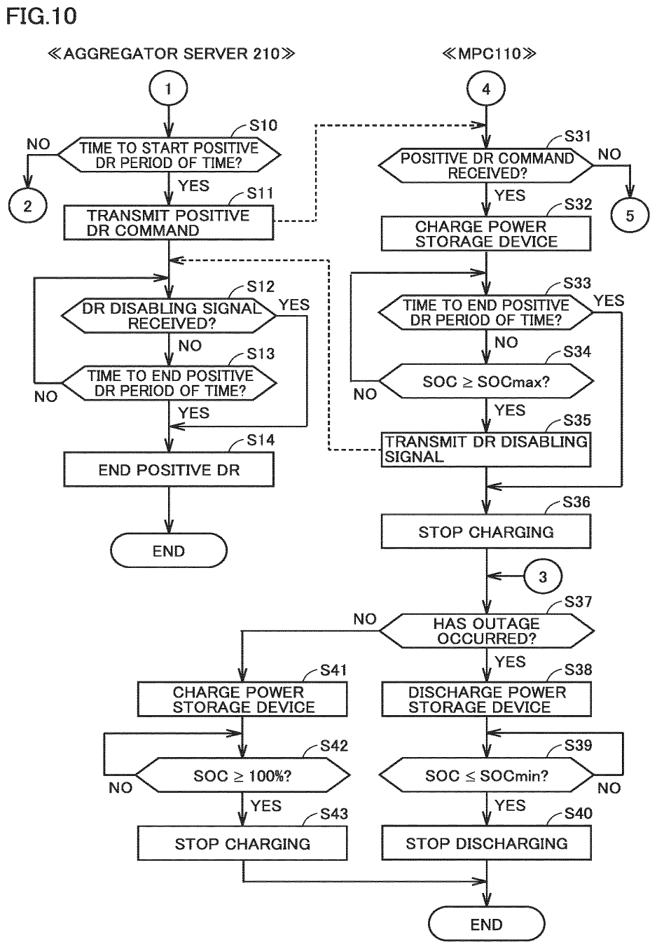

FIGS. 9 and 10 are flowcharts of a procedure of a process for how charging/discharging power storage device 130 is controlled according to the present embodiment. This flowchart is invoked from a main routine and executed for example when a predetermined condition is established. In the figures, a process performed by aggregator server 210 is indicated on the left side, and a process performed by MPC 110 (or controller 23) is indicated on the right side. While each step is implemented through software processing performed by aggregator server 210 or controller 23, it may be implemented by hardware disposed in aggregator server 210 or controller 23. Hereinafter, a step is abbreviated as S.

In S01, when a request for a demand and supply adjustment of power system 200 is received from an electric utility company, aggregator server 210 obtains contents of a power adjustment. The contents of the power adjustment include a type of DR (positive DR/negative DR), an amount of DR (an amount of a power adjustment), and a DR period of time (i.e., a time to start a DR and a time to end the DR).

In S02, aggregator server 210 sets a type of DR, an amount of DR, and a DR period of time to be requested to each consumer. After S02, aggregator server 210 waits for the DR period of time to be started.

In step S03, aggregator server 210 determines whether a time to preannounce the DR has arrived. The time to preannounce the DR is a time before the DR starts by a predetermined period of time.

When the time to preannounce the DR arrives (YES in S03), aggregator server 210 transmits a DR preannouncement signal to consumer 100 in S04. The DR preannouncement signal is a signal to preannounce that a DR will start. The DR preannouncement signal is transmitted, and thereafter when a time to start a negative DR period of time arrives (YES in S05), aggregator server 210 transmits a negative DR command to consumer 100 in S06.

In MPC 110, when the DR preannouncement signal is received from aggregator server 210 (YES in S21), then, in S22, controller 23 controls bidirectional converter 8 to perform a discharging operation to supply load 120 with power stored in power storage device 130.

During the discharging operation, in S23, controller 23 determines whether power storage device 130 has an SOC reduced to the SOCwait or less. If the SOC is reduced to the SOCwait or less (YES in S23), then, in S24, controller 23 stops operating bidirectional converter 8 and hence stops discharging power storage device 130.

The DR preannouncement signal is received, and thereafter when controller 23 receives the negative DR command from aggregator server 210 (YES in S25), the controller responds to the negative DR command in S26 by controlling bidirectional converter 8 to perform a discharging operation to supply load 120 with power stored in power storage device 130 (see FIG. 5).

While the negative DR is executed, in S27, controller 23 determines whether a time to end the negative DR period of time has arrived. If the time to end the negative DR period of time has not arrived (No in S27), then, in S28, controller 23 determines whether power storage device 130 has an SOC reduced to the SOCbackup or less. If the SOC exceeds the SOCbackup (NO in S28), the process returns to S27. In contrast, when the SOC is reduced to the SOCbackup or less (YES in S28), the process proceeds to S29, and controller 23 transmits a DR disabling signal to aggregator server 210.

If the DR disabling signal is transmitted in S29 or if the time to end the negative DR period of time has arrived (YES in S27), then, in S30, controller 23 stops operating bidirectional converter 8 and hence stops discharging power storage device 130.

While the negative DR is executed, in S07, aggregator server 210 determines whether the DR disabling signal is received from controller 23. If the DR disabling signal is not received (No in S07), then, in S08, aggregator server 210 determines whether the time to end the negative DR period of time has arrived.

If the DR disabling signal is received (YES in S07) or if the time to end the negative DR period of time has arrived (YES in S08), aggregator server 210 ends executing the negative DR in S09.

In MPC 110, controller 23 determines in S37 of FIG. 10 whether power system 200 fails. The controller makes a decision of YES in S37 if power system 200 supplies alternating voltage VI lower than the lower limit value. In contrast, when alternating voltage VI is equal to or larger than the lower limit value, the controller makes a decision of NO in S37.

If power system 200 is healthy (NO in S37), then, in S41, controller 23 controls bidirectional converter 8 to perform a charging operation of power storage device 130 (see FIG. 3). During the charging operation, in S42, controller 23 determines whether power storage device 130 has an SOC equal to or larger than 100%. If the SOC is equal to or larger than 100% (YES in S42), then, in S43, controller 23 stops operating bidirectional converter 8 and hence stops charging power storage device 130.

Returning to S37, when power system 200 fails (YES in S37), then, in S38, controller 23 controls bidirectional converter 8 to perform a discharging operation of power storage device 130 (see FIG. 4). During the discharging operation, in S39, controller 23 determines whether power storage device 130 has an SOC equal to or less than the SOCmin. If the SOC is equal to or less than the SOCmin (YES in S39), then, in S40, controller 23 stops operating bidirectional converter 8 and hence stops discharging power storage device 130.

Returning to S05, when the time to start the negative DR period of time has not arrived (NO in S05), aggregator server 210 proceeds to S10 in FIG. 10, and determines whether a time to start a positive DR period of time has arrived. If the time to start the positive DR period of time has not arrived (NO in S10), the process returns to S05.

The DR preannouncement signal is transmitted, and thereafter when the time to start the positive DR period of time arrives (YES in S10), then, in S11, aggregator server 210 transmits a positive DR command to consumer 100.

If MPC 110 receives the positive DR command from aggregator server 210 (YES in S31), then, in S32, controller 23 controls bidirectional converter 8 to perform a charging operation of power storage device 130 (see FIG. 7).

While the positive DR is executed, in S33, controller 23 determines whether the time to end the positive DR period of time has arrived. If the time to end the positive DR period of time has not arrived (No in S33), then, in S34, controller 23 determines whether power storage device 130 has an SOC equal to or larger than the SOCmax. If the SOC is less than the SOCmax (NO in S34), the process returns to S33. If the SOC is equal to or larger than the SOCmax (YES in S34), then in S35 controller 23 transmits a DR disabling signal to aggregator server 210.

If the DR disabling signal is transmitted in S35 or if the time to end the positive DR period of time has arrived (YES in S33), controller 23 stops operating bidirectional converter 8 and hence stops charging power storage device 130 in S36.

While the positive DR is executed, in S12, aggregator server 210 determines whether the DR disabling signal has been received from controller 23. If the DR disabling signal has not been received (NO in S12), aggregator server 210 determines in S13 whether the time to end the positive DR period of time has arrived.

If the DR disabling signal is received (YES in S12) or if the time to end the positive DR period of time has arrived (YES in S13), aggregator server 210 ends executing the positive DR in S14.

Thus, the power supply apparatus according to the present embodiment can contribute to demand/supply adjustment for power system 200 as requested by an electric utility company while ensuring compensation for load 120 for outage.

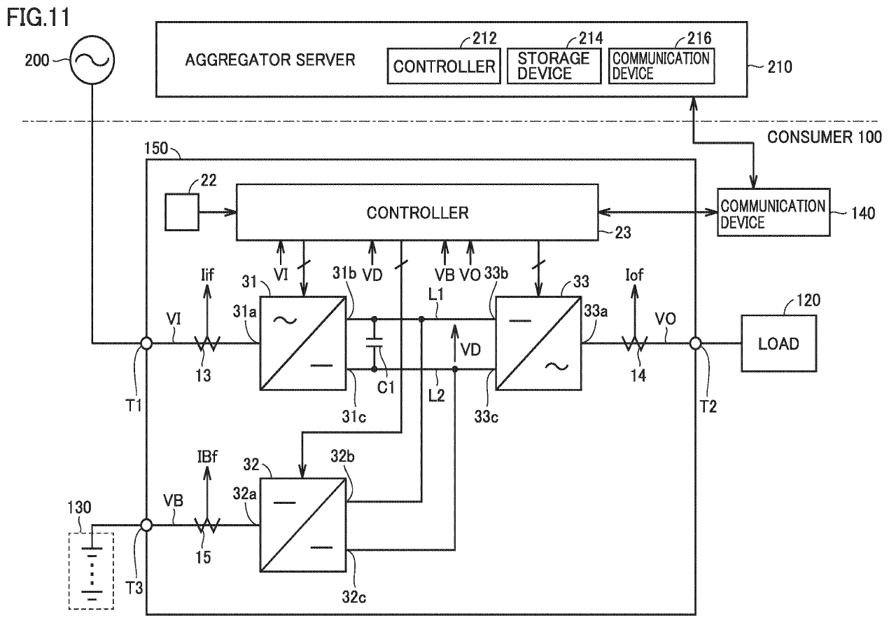

While in the above-described embodiment MPC 110 has been described as one manner of the power supply apparatus according to the present embodiment, the power supply apparatus is not limited to MPC 11, and it may be a UPS. FIG. 11 is a diagram for illustrating a configuration of a power supply apparatus according to a modification of the present embodiment. In FIG. 11, a UPS will be described as another manner of the power supply apparatus.

As shown in FIG. 11, a UPS 150 differs from MPC 110 shown in FIG. 1 in that the former comprises a converter 31, an inverter 33, and a bidirectional chopper 32 in place of VCBs 1, 5 and 21, HSS 2, and power converter 7. While UPS 150 receives a three-phase alternating voltage from power system 200 and supplies the three-phase alternating voltage to load 120, FIG. 11 illustrates only a circuit for one phase to simplify the figure and the description.

Converter 31 has an alternate-current terminal 31a, a positive voltage terminal 31b, and a negative voltage terminal 31c. Bidirectional chopper 32 has a direct-current terminal 32a, a positive voltage terminal 32b, and a negative voltage terminal 32c. Inverter 33 has an alternate-current terminal 33a, a positive voltage terminal 33b, and a negative voltage terminal 33c.

Converter 31 has alternate-current terminal 31a connected to input terminal T1. Current detector 13 detects an instantaneous value of a current Ii flowing between input terminal T1 and alternate-current terminal 1a, and provides a signal Iif indicating the detected value to controller 23.

Bidirectional chopper 32 has direct-current terminal 32a connected to direct-current terminal T3. Current detector 15 detects an instantaneous value of direct current IB flowing between direct-current terminal T2 and direct-current terminal 2a, and provides a signal IBf indicating the detected value to controller 23.

Inverter 33 has alternate-current terminal 33a connected to output terminal T2. Current detector 14 detects an instantaneous value of a current Io flowing between alternate-current terminal 34a and output terminal T2, and provides a signal Iof indicating the detected value to controller 23.

Direct-current lines L1 and L2 have their respective one terminals connected to converter 31 at positive voltage terminal 31b and negative voltage terminal 31c, respectively. Direct-current lines L1 and L2 have their respective other terminals connected to inverter 33 at positive voltage terminal 33b and negative voltage terminal 33c, respectively. Direct-current lines L1 and L2 are connected to bidirectional chopper 32 at positive voltage terminal 32a and negative voltage terminal 32c, respectively.

A capacitor C1 is connected between direct-current lines L1 and L2 to stabilize and smooth direct voltage VD between direct-current lines L1 and L2. An instantaneous value of direct voltage VD is detected by controller 23.

Converter 31 is controlled by controller 23, and when power system 200 is healthy, the converter receives alternating voltage VI from power system 200 via input terminal T1, converts the received alternating voltage to direct voltage VD, and outputs the direct voltage between direct-current lines L1 and L2. When power system 200 fails, converter 31 is stopped from operating. When power system 200 is healthy, controller 23 controls converter 31 so that direct voltage VD between direct-current lines L1 and L2 is reference voltage VDr. Converter 31 corresponds to one embodiment of a “second power converter”.

Bidirectional chopper 32 is controlled by controller 23. When power system 200 is healthy, bidirectional chopper 32 receives direct-current power from converter 31 through direct-current lines L1 and L2 and stores the received direct-current power in power storage device 130. When power system 200 fails, bidirectional chopper 32 converts direct voltage VB of power storage device 130 to direct voltage VD and outputs the direct voltage between positive voltage terminal 32b and negative voltage terminal 32c. Bidirectional chopper 32 is configured to be capable of selectively performing a charging operation to store direct-current power in power storage device 130 and a discharging operation to output the direct-current power of power storage device 130 between direct-current lines L1 and L2. Bidirectional chopper 32 corresponds to one embodiment of the “first power converter”.

When power system 200 is healthy, controller 23 controls bidirectional chopper 32 so that direct voltage VB is reference direct voltage VBr. Reference direct voltage VBr is set based on an OCV that power storage device 130 has when power storage device 130 is in the fully charged state (SOC=100%) on the OCV-SOC curve of power storage device 130. When power system 200 fails, controller 23 controls bidirectional chopper 32 so that direct voltage VD is reference voltage VDr.

Inverter 33 is controlled by controller 23. When power system 200 is healthy, inverter 33 receives direct voltage VD from converter 31 through direct-current lines L1 and L2 and converts the received direct voltage to alternating voltage VO, and supplies the alternating voltage to load 120. When power system 200 fails, inverter 33 receives direct voltage VD from power storage device 130 via bidirectional chopper 32 and through direct-current lines L1 and L2 and converts the direct voltage to alternating voltage VO, and supplies the alternating voltage to load 120. Inverter 33 outputs voltage VO, which is controllable to have a desired value. Controller 23 controls inverter 33 so that alternating output voltage VO is reference alternating voltage VOr. Inverter 33 corresponds to one embodiment of a “third power converter”.

Controller 23 generally controls UPS 150 based on alternating voltage VI, alternating current Ii, direct voltages VD and VB, direct current IB, alternating voltage VO, alternating current Io, a signal received from operation unit 22, and so forth.

When power system 200 is healthy, and a DR preannouncement signal is received from aggregator server 210, controller 23 controls bidirectional chopper 32 so that a total power of alternating-current power supplied from power system 200 via converter 31 and inverter 33 and alternating-current power supplied from power storage device 130 via bidirectional chopper 32 and inverter 33 is supplied to load 120. When power storage device 130 has an SOC reduced to the SOCwait, controller 23 stops discharging power storage device 130. That is, before a DR is started, controller 23 discharges power storage device 130 while ensuring that an amount of power is stored for compensation for outage. When a DR is a positive DR, power storage device 130 can receive a portion of power supplied from power system 200 while the DR is executed.

The DR preannouncement signal is received, and thereafter when a negative DR command is received from aggregator server 210, controller 23 controls bidirectional chopper 32 so that a total power of alternating-current power supplied from power system 200 via converter 31 and inverter 33 and alternating-current power supplied from power storage device 130 via bidirectional chopper 32 and inverter 33 is supplied to load 120. This can reduce alternating-current power supplied from power system 200 to consumer 100, and consumer 100 can contribute to suppressing an amount of demand for power, as requested by an electric utility company. Note, however, that when power storage device 130 has an SOC reduced to the SOCbackup or less, controller 23 transmits the DR disabling signal to aggregator server 210 to ensure that power storage device 130 has an amount of power stored therein for compensation for outage.

The DR preannouncement signal is received, and thereafter when a positive DR command is received from aggregator server 210, controller 23 controls bidirectional chopper 32 to perform a charging operation to store direct-current power in power storage device 130. This can increase alternating-current power supplied from power system 200 to consumer 100, and consumer 100 can contribute to an increase in amount of demand for power, as requested by the electric utility company. Note that responding to the DR preannouncement signal by discharging power storage device 130 while ensuring that an amount of power is stored for compensation for outage allows power storage device 130 to receive a portion of power supplied from power system 200 while the positive DR is executed.

It should be understood that the embodiments disclosed herein are illustrative and non-restrictive in any respect. The scope of the present disclosure is defined by the terms of the claims, and is intended to encompass any modifications within the meaning and scope equivalent to the terms of the claims.

### REFERENCE SIGNS LIST

1, 5, 6, 21 VCB, 2 high speed switch, 7 power converter, 8 bidirectional converter, 10, 13-15 current detector, 11 reactor, 12, C1 capacitor, 20 transformer, 22 operation unit, 23, 212 controller, 31 converter, 32 bidirectional chopper, 33 inverter, 100 consumer, 110 MPC, 120 load, 130 power storage device, 140, 216 communication device, 150 UPS, 200 power system, 210 aggregator server, 214 storage device, 230 CPU, 232 memory, 234 I/O circuit, T1 input terminal, T2 output terminal, T3 direct-current terminal, L1, L2 direct-current line.

1. A power supply apparatus that is connected between a power system and a load, supplies the load with a first alternating-current power supplied from the power system when the power system is healthy, and supplies the load with a second alternating-current power when the power system fails, the power supply apparatus comprising:
a first power converter that selectively performs a charging operation to convert a portion of the first alternating-current power to direct-current power and store the direct-current power in a power storage device, and a discharging operation to convert direct-current power in the power storage device to the second alternating-current power; and
a controller communicatively connected to a server that adjusts power demand and supply in the power system, wherein
when the power system fails, the controller controls the discharging operation in the first power converter to supply the load with the second alternating-current power,
for the power storage device, a reference SOC value and a standby SOC larger than the reference SOC value are set, the reference SOC value being equal to or larger than an SOC necessary for supplying the second alternating-current power from the power storage device to the load after the power system fails before a predetermined period of time for compensation elapses,
when the power system is healthy,
the controller controls the charging operation in the first power converter so that the power storage device attains a fully charged state, and
when a demand response preannouncement signal is received from the server to adjust an amount of demand in the power system,
the controller controls the discharging operation in the first power converter to supply the load with a total power of the first alternating-current power and the second alternating-current power,
in response to the power storage device having an SOC reduced to the standby SOC, the controller stops the discharging operation, and
in response to a demand response command received from the server, the controller controls the discharging operation or the charging operation in the first power converter.

2. The power supply apparatus according to claim 1, wherein when the controller receives the preannouncement signal and subsequently receives a negative demand response command from the server to reduce the amount of demand in the power system, the controller
controls the discharging operation in the first power converter to supply the load with a total power of the first alternating-current power and the second alternating-current power, and
stops the discharging operation in response to the power storage device having an SOC reduced to the reference SOC value.

3. The power supply apparatus according to claim 2, wherein when the controller receives the negative demand response command from the server, the controller transmits a demand response disabling signal to the server in response to the power storage device having an SOC reduced to the reference SOC value.

4. The power supply apparatus according to claim 1, wherein when the controller receives the preannouncement signal and subsequently receives a positive demand response command from the server to increase the amount of demand in the power system, the controller
controls the charging operation in the first power converter, and
stops the charging operation in response to the power storage device having an SOC having reached an upper SOC limit value smaller than the fully charged state.

5. The power supply apparatus according to claim 4, wherein when the controller receives the positive demand response command from the server, the controller transmits a demand response disabling signal to the server in response to the power storage device having an SOC having reached the upper SOC limit value.

6. The power supply apparatus according to claim 4, wherein
the controller switches the charging operation of the power storage device from constant current charging to constant voltage charging depending on an SOC of the power storage device, and
the upper SOC limit value is set based on an SOC that the power storage device has when the constant current charging is switched to the constant voltage charging.

7. The power supply apparatus according to claim 1, further comprising a switch having a first terminal connected to the power system and a second terminal connected to the load, wherein
the controller turns on the switch when the power system is healthy, and the controller turns off the switch when the power system fails, and
the first power converter is connected between the second terminal and the power storage device.

8. The power supply apparatus according to claim 1, further comprising:
a second power converter that converts the first alternating-current power to direct-current power and supplies the direct-current power to a direct-current line when the power system is healthy, and that is stopped from operating when the power system fails; and
a third power converter that receives direct-current power from the direct-current line, converts the received direct-current power to a third alternating-current power, and supplies the third alternating-current power to the load, wherein
the first power converter is connected between the direct-current line and the power storage device.

9. The power supply apparatus according to claim 1, wherein the power storage device is a lithium ion battery.

10. The power supply apparatus according to claim 2, further comprising a switch having a first terminal connected to the power system and a second terminal connected to the load, wherein
the controller turns on the switch when the power system is healthy, and the controller turns off the switch when the power system fails, and
the first power converter is connected between the second terminal and the power storage device.

11. The power supply apparatus according to claim 2, further comprising:
a second power converter that converts the first alternating-current power to direct-current power and supplies the direct-current power to a direct-current line when the power system is healthy, and that is stopped from operating when the power system fails; and
a third power converter that receives direct-current power from the direct-current line, converts the received direct-current power to a third alternating-current power, and supplies the third alternating-current power to the load, wherein
the first power converter is connected between the direct-current line and the power storage device.

12. The power supply apparatus according to claim 2, wherein the power storage device is a lithium ion battery.

13. The power supply apparatus according to claim 3, further comprising a switch having a first terminal connected to the power system and a second terminal connected to the load, wherein
the controller turns on the switch when the power system is healthy, and the controller turns off the switch when the power system fails, and
the first power converter is connected between the second terminal and the power storage device.

14. The power supply apparatus according to claim 3, further comprising:
a second power converter that converts the first alternating-current power to direct-current power and supplies the direct-current power to a direct-current line when the power system is healthy, and that is stopped from operating when the power system fails; and
a third power converter that receives direct-current power from the direct-current line, converts the received direct-current power to a third alternating-current power, and supplies the third alternating-current power to the load, wherein
the first power converter is connected between the direct-current line and the power storage device.

15. The power supply apparatus according to claim 3, wherein the power storage device is a lithium ion battery.

16. The power supply apparatus according to claim 4, further comprising a switch having a first terminal connected to the power system and a second terminal connected to the load, wherein
the controller turns on the switch when the power system is healthy, and the controller turns off the switch when the power system fails, and
the first power converter is connected between the second terminal and the power storage device.

17. The power supply apparatus according to claim 4, further comprising:
a second power converter that converts the first alternating-current power to direct-current power and supplies the direct-current power to a direct-current line when the power system is healthy, and that is stopped from operating when the power system fails; and
a third power converter that receives direct-current power from the direct-current line, converts the received direct-current power to a third alternating-current power, and supplies the third alternating-current power to the load, wherein
the first power converter is connected between the direct-current line and the power storage device.

18. The power supply apparatus according to claim 4, wherein the power storage device is a lithium ion battery.
